(19) United States
(12) Patent Application Publication
(10) Pub. No.: US 2026/0262234 A1
(43) Pub. Date: Sep. 3, 2026

(54) SEMICONDUCTOR DEVICES AND FABRICATION METHODS THEREOF

(71) Applicant: Vanguard International Semiconductor Corporation, Hsinchu (TW)

(72) Inventors: Cheng-Ping Chang, Hualien County (TW); Yung-Hsiang Chen, Hsinchu City (TW); Chien-Hui Li, Hsinchu County (TW); Chien-Hsun Wu, Hsinchu County (TW)

(73) Assignee: Vanguard International Semiconductor Corporation, Hsinchu (TW)

(21) Appl. No.: 19/068,008

(22) Filed: Mar. 3, 2025

(51) Int. Cl. H10D 1/47; H10D 1/00

(52) U.S. Cl. CPC H10D 1/47; H10D 1/021

(57) ABSTRACT

A semiconductor device includes a substrate, a thin film resistor, a lead structure, and a passivation layer. The thin film resistor is disposed above the substrate and has a first end and a second end. The lead structure is disposed above the substrate and includes a conductive layer stacked on an etch stop layer. The etch stop layer is in direct contact with and covers the first end and the second end of the thin film resistor. The passivation layer covers the thin film resistor and the lead structure.

### BACKGROUND OF THE INVENTION

### 1. Field of the Invention

The present disclosure relates generally to semiconductor manufacturing technology, and more particularly to semiconductor devices including thin film resistors and fabrication methods thereof.

### 2. Description of the Prior Art

Thin film resistors are resistors whose area is much larger than their thickness. Thin film resistors have a low temperature coefficient of resistance (TCR) and a stable resistance value that is not easily affected by temperature. Therefore, thin film resistors are important components in analog circuits. For example, thin film resistors are often integrated into circuits such as active filters, resistor-string digital-to-analog converters, and amplifiers.

In the semiconductor manufacturing process of integrating thin film resistors, thin film resistance material is usually deposited on an inter-metal dielectric (IMD) layer of an intermediate layer in an interconnect structure. Then, the thin film resistance material is patterned to form a thin film resistor within the interconnect structure. However, because thin film resistors are very thin, they are easily damaged by the etching process used to pattern the thin film resistance material and are also easily affected by stress. Therefore, many challenges remain in the manufacture of thin film resistors.

### SUMMARY OF THE INVENTION

In view of this, the present disclosure provides semiconductor devices including thin film resistors and fabrication methods thereof. The thin film resistor is located between an uppermost dielectric layer and a passivation layer in an interconnect structure, thereby reducing stress on the thin film resistor. A lead structure is disposed at the end of the thin film resistor. This lead structure functions as both a connecting wire and a contact pad. Moreover, the composition of the lead structure serves as a hard mask for etching and also protects the thin film resistor during manufacturing, thereby reducing the number of photomasks and process steps.

According to an embodiment of the present disclosure, a semiconductor device is provided and includes a substrate, a thin film resistor, a lead structure, and a passivation layer. The thin film resistor is disposed above the substrate and has a first end and a second end. The lead structure is disposed above the substrate and includes a conductive layer stacked on an etch stop layer. The etch stop layer is in direct contact with and covers the first end and the second end of the thin film resistor. The passivation layer covers the thin film resistor and the lead structure.

According to an embodiment of the present disclosure, a method of fabricating a semiconductor device is provided and includes the following steps. A thin film resistance material layer is deposited above a substrate. The thin film resistance material layer is patterned to form a thin film resistor having a first end and a second end. An etch stop material layer and a conductive material layer are deposited above the substrate in sequence to cover the thin film resistor. The conductive material layer is patterned to form a conductive layer. The etch stop material layer is patterned to form an etch stop layer. The etch stop layer and the conductive layer constitute a lead structure. The etch stop layer is in direct contact with and covers the first end and the second end of the thin film resistor. In addition, a passivation layer is formed to cover the thin film resistor and the lead structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 shows a schematic top view and a schematic cross-sectional view of a semiconductor device according to an embodiment of the present disclosure.

FIG. 2 shows a schematic top view and a schematic cross-sectional view of a semiconductor device according to another embodiment of the present disclosure.

FIG. 3 shows a schematic top view and a schematic cross-sectional view of a semiconductor device according to further another embodiment of the present disclosure.

FIG. 4 shows a schematic top view and a schematic cross-sectional view of a semiconductor device according to yet another embodiment of the present disclosure.

FIG. 5 and FIG. 6 are schematic cross-sectional views of some stages of a method of fabricating a semiconductor device according to an embodiment of the present disclosure.

FIG. 7 and FIG. 8 are schematic cross-sectional views of some stages of a method of fabricating a semiconductor device according to another embodiment of the present disclosure.

FIG. 9, FIG. 10 and FIG. 11 are schematic cross-sectional of some stages of a method of fabricating a semiconductor device according to further another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the semiconductor structure in use or operation in addition to the orientation depicted in the figures. For example, if the semiconductor structure in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to semiconductor devices including thin film resistors and fabrication methods thereof. The thin film resistor is located between an uppermost dielectric layer and a passivation layer in an interconnect structure, thereby reducing stress on the thin film resistor and improving its electrical performance. A lead structure is in direct contact with and overlaps the end of the thin film resistor to create an electrical connection. The lead structure includes a conductive layer stacked on an etch stop layer. During manufacturing, the conductive layer serves as a hard mask for etching, and an etch stop material layer protects the thin film resistor. In some embodiments, the thin film resistor may be an independent component or electrically connected to the interconnect structure. The lead structure functions as both a connecting wire and a contact pad. In some embodiments, the lead structure also serves as a top metal layer of the interconnect structure, so that the thin film resistor is electrically coupled to other components in a substrate through the interconnect structure. Moreover, according to embodiments of the present disclosure, the number of photomasks and process steps required for fabricating the semiconductor devices including the thin film resistors is reduced.

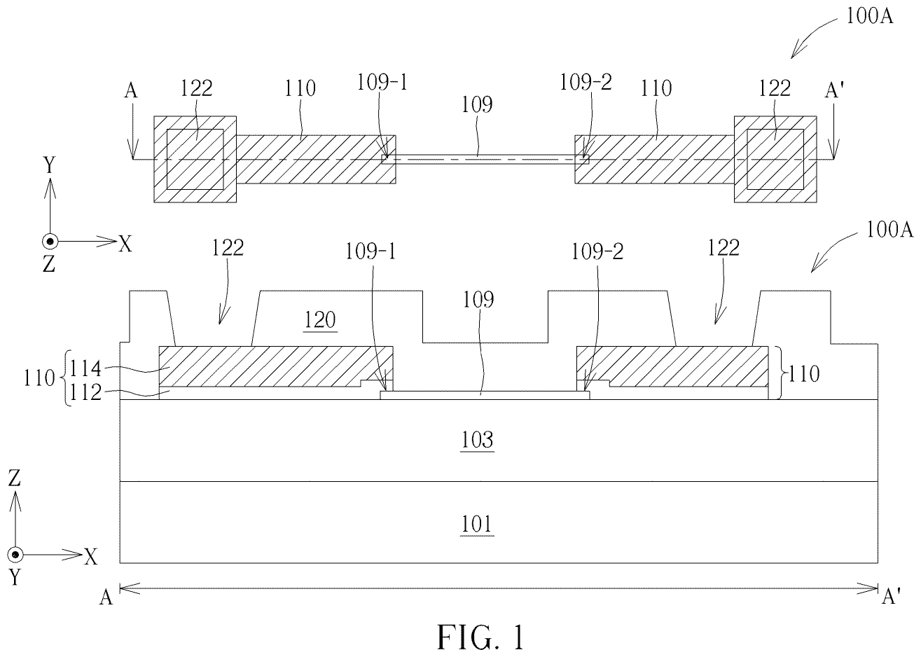

FIG. 1 shows a schematic top view and a schematic cross-sectional view of a semiconductor device 100A according to an embodiment of the present disclosure, where the cross-sectional view is taken along line segment A-A′ in the top view. The semiconductor device 100A includes a substrate 101, a dielectric layer 103, a thin film resistor 109, a lead structure 110, and a passivation layer 120. To make the diagram concise and easy to understand, the passivation layer 120, the dielectric layer 103, and the substrate 101 are omitted from the top view. The substrate 101 may be a semiconductor substrate, a sapphire substrate, a ceramic substrate or other suitable substrate. Multiple transistors and/or other electronic components (not shown) may be formed in the substrate 101. In this embodiment, the thin film resistor 109 is an independent component that is not electrically connected to the transistors and/or other electronic components in the substrate 101. The dielectric layer 103 is disposed on the substrate 101. The thin film resistor 109 and the lead structure 110 are disposed on the dielectric layer 103. The bottom surfaces of the thin film resistor 109 and the lead structure 110, and the top surface of the dielectric layer 103 are coplanar. The passivation layer 120 covers the thin film resistor 109 and the lead structure 110, and has an opening 122 to expose the lead structure 110.

The thin film resistor 109 has a low temperature coefficient of resistance (TCR), typically less than 50 ppm/K. In some embodiments, the composition of the thin film resistor 109 may be silicon chromium (SiCr), nickel chromium (NiCr), or nickel chromium silicon (NiCrSi); or alloy derivatives of silicon chromium (SiCr), such as silicon chromium carbide (SiCCr), silicon chromium oxide (CrSiO), silicon chromium nitride (CrSiN), and silicon chromium doped with carbon and oxygen (SiCrCO); or alloy derivatives of nickel chromium (NiCr), such as nickel chromium doped with carbon and oxygen (NiCrCO), aluminum nickel chromium (AlNiCr), and titanium nickel chromium (TiNiCr); other resistance materials, such as tantalum (Ta), tantalum aluminum (TaAl), and tantalum silicide (TaSi₂); or other suitable copper (Cu) alloys, such as CuNi, CuSn, CuNiMn, CuMnSn, CuMnAl, etc. The thickness of the thin film resistor 109 is typically less than 1 micrometer (μm), for example, about 50 angstroms (Å) to 100 Å. The thickness of the thin film resistor 109 may be adjusted to meet the required resistance value. Furthermore, as shown in the top view of FIG. 1, the thin film resistor 109 may be a long strip, and its resistance value may be controlled by adjusting its width and length.

As shown in the cross-sectional view of FIG. 1, the lead structure 110 includes a conductive layer 114 stacked on an etch stop layer 112. The etch stop layer 112 is in direct contact with and covers a first end 109-1 and a second end 109-2 of the thin film resistor 109. In some embodiments, the composition of the etch stop layer 112 includes titanium tungsten (TiW) or titanium nitride (TiN). The conductive layer 114 includes a titanium nitride (TiN) layer stacked on an aluminum copper (AlCu) layer, where the AlCu layer is in direct contact with the etch stop layer 112. In the semiconductor device 100A, as shown in the top view of FIG. 1, the pattern of the conductive layer 114 may completely overlap the pattern of the etch stop layer 112. In the vertical projection direction, the side surface of the conductive layer 114 may be aligned with the side surface of the etch stop layer 112. The composition of the passivation layer 120 includes silicon oxide, silicon nitride, silicon oxynitride or other insulating materials. An opening 122 in the passivation layer 120 exposes the lead structure 110.

According to some embodiments of the present disclosure, a portion of the lead structure 110 is in direct contact with and covers the first end 109-1 and the second end 109-2 of the thin film resistor 109, thereby serving as a contact electrode for the thin film resistor 109. The end portion of the lead structure 110 serves as a contact pad and is electrically connected to an external component through the opening 122 in the passivation layer 120. In addition, portions of the lead structure 110 serve as connecting wires and are distributed on the dielectric layer 103 according to layout requirements. For example, portions of the lead structure 110 may connect multiple parallel thin film resistors 109 in series. Moreover, openings may be absent in the passivation layer 120 above portions of the lead structure 110. Therefore, the lead structure 110 can simultaneously serve as the contact electrode, the connecting wire and the contact pad for the thin film resistor 109.

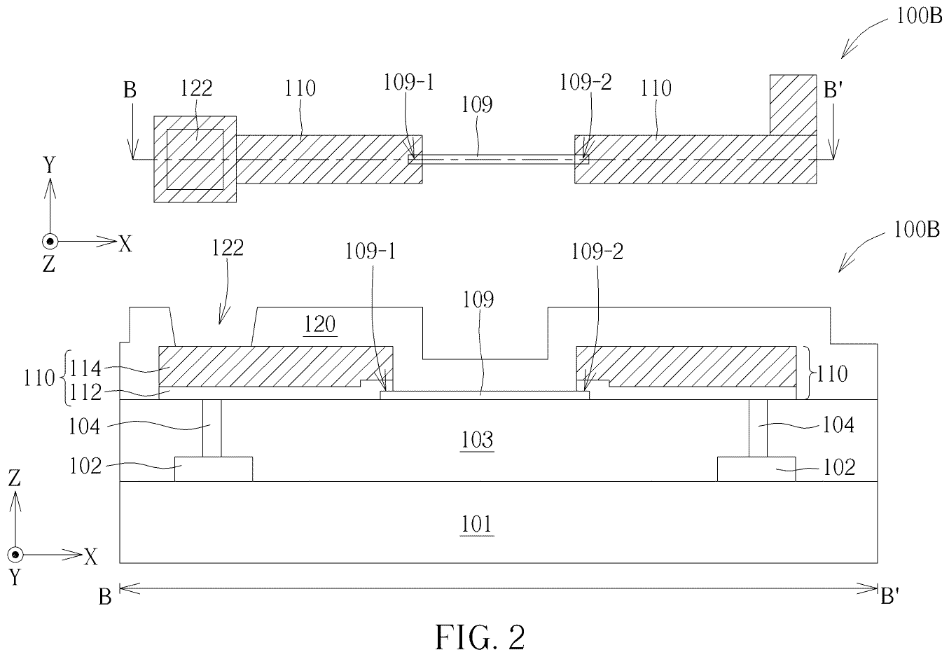

FIG. 2 shows a schematic top view and a schematic cross-sectional view of a semiconductor device 100B according to another embodiment of the present disclosure, where the cross-sectional view is taken along line segment B-B′ in the top view. Compared with the semiconductor device 100A in FIG. 1, a metal interconnect layer 102 and a via 104 are further disposed in the dielectric layer 103 of the semiconductor device 100B. The dielectric layer 103 is also referred to as an inter-metal dielectric (IMD) layer. The via 104 is located on the metal interconnect layer 102 to electrically connect the metal interconnect layer 102 to the lead structure 110. A portion of the lead structure 110 may serve as a top metal (MT) layer. Although only one dielectric layer 103, one metal interconnect layer 102, and one via 104 are shown in FIG. 2, multiple IMD layers may be disposed on the substrate 101, with multiple metal interconnect layers 102 and multiple vias 104 disposed within these IMD layers to construct an interconnect structure. In the semiconductor device 100B, a portion of the lead structure 110 serves as a contact electrode for the thin film resistor 109. Some portions of the lead structure 110 serve as connecting wires for the thin film resistor 109 and a top metal layer of the interconnection structure. The thin film resistor 109 may be electrically coupled to the transistors and/or other electronic components in the substrate 101 through the lead structure 110, and both the metal interconnect layer 102 and the via 104 in the dielectric layer 103, thereby integrating the thin film resistor 109 with the transistors, such as complementary metal-oxide-semiconductor (CMOS) transistors, in the substrate 101. Details of other features of the semiconductor device 100B may be found in the related description of FIG. 1 and will not be repeated here.

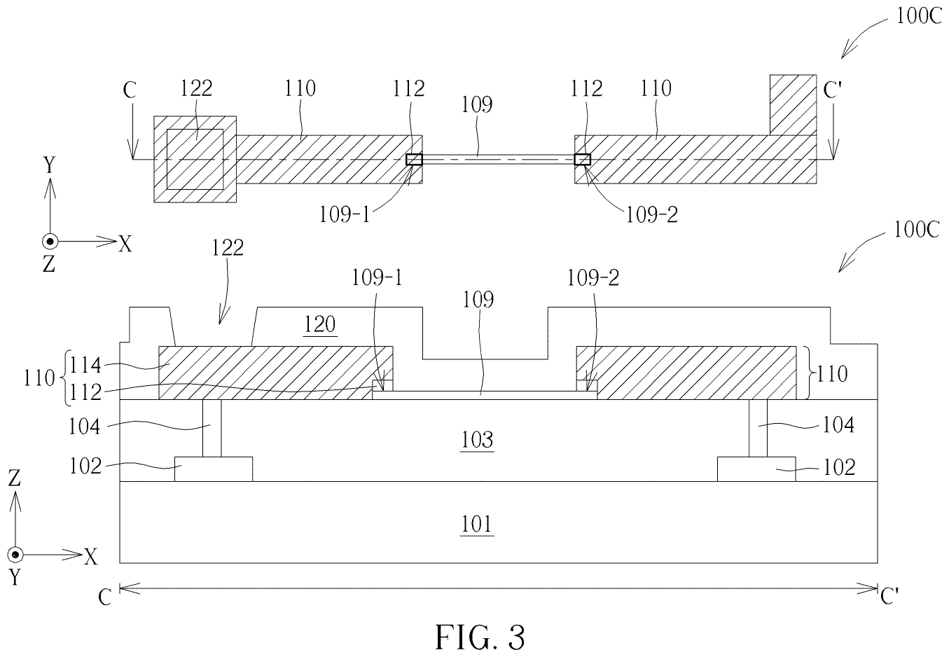

FIG. 3 shows a schematic top view and a schematic cross-sectional view of a semiconductor device 100C according to further another embodiment of the present disclosure, where the cross-sectional view is taken along line segment C-C′ in the top view. Compared with the semiconductor device 100B in FIG. 2, in the vertical projection direction, the outer side surface of the etch stop layer 112 of the semiconductor device 100C is aligned with the side surface of the thin film resistor 109. The bottom surface of the thin film resistor 109, the bottom surface of the conductive layer 114, and the top surface of the dielectric layer 103 are coplanar. The conductive layer 114 covers both the outer side surface of the etch stop layer 112 and the side surface of the thin film resistor 109. In the semiconductor device 100C, the conductive layer 114 may include a titanium nitride (TiN) layer, an aluminum copper (AlCu) layer, and a titanium nitride (TiN) layer stacked in sequence from bottom to top. The bottommost TiN layer is in direct contact with and covers the dielectric layer 103. The AlCu layer is in direct contact with and covers the etch stop layer 112. In the semiconductor device 100C, a first portion of the conductive layer 114 is in direct contact with and stacked on the etch stop layer 112. A second portion of the conductive layer 114 is in direct contact with and stacked on the dielectric layer 103. In the lead structure 110, the etch stop layer 112 and the first portion of the conductive layer 114 together serve as a contact electrode for the thin film resistor 109. The second portion of the conductive layer 114 serves as a connecting wire for the thin film resistor 109 and a top metal (MT) layer of the interconnection structure. The via 104 electrically connects the metal interconnection layer 102 to the conductive layer 114. Therefore, the thin film resistor 109 is electrically coupled to the transistors and/or other electronic components in the substrate 101 through the conductive layer 114, and the metal interconnection layer 102 and the via 104 in the dielectric layer 103. Details of other features of the semiconductor device 100C may be found in the related descriptions of FIG. 1 and FIG. 2, which will not be repeated here.

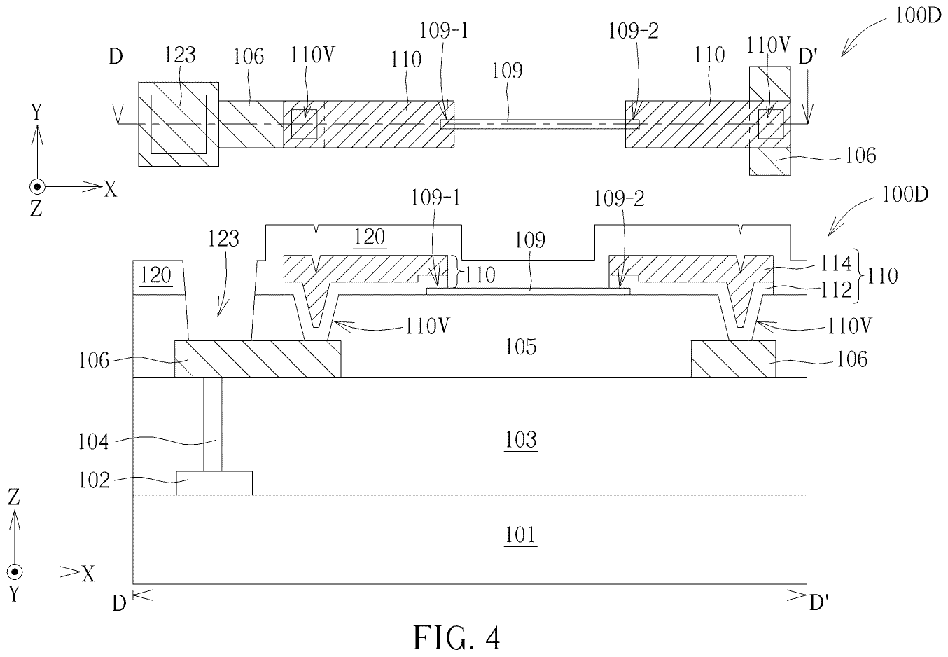

FIG. 4 shows a schematic top view and a schematic cross-sectional view of a semiconductor device 100D according to yet another embodiment of the present disclosure, where the cross-sectional view is taken along line segment D-D′ in the top view. Compared with the semiconductor device 100B in FIG. 2, the semiconductor device 100D further includes a dielectric layer 105, a top metal layer 106, and a contact via 110V. The dielectric layer 105 is disposed on the dielectric layer 103. The top metal layer 106 and the contact via 110V are disposed in the dielectric layer 105. The thin film resistor 109 is located between the passivation layer 120 and the top metal layer 106. The contact via 110V is formed by filling a hole in the dielectric layer 105 with the etch stop layer 112 and the conductive layer 114 of the lead structure 110. The contact via 110V electrically connects the top metal layer 106 to the lead structure 110. The thin film resistor 109 is electrically connected to the top metal layer 106 through the lead structure 110 and the contact via 110V. Furthermore, a common opening 123 is disposed in the passivation layer 120 and the dielectric layer 105 of the semiconductor device 100D to expose the top metal layer 106. External circuits and/or components may be electrically connected to the top metal layer 106 through the common opening 123. In the semiconductor device 100D, a portion of the lead structure 110 serves as a contact electrode for the thin film resistor 109. Some portions of the lead structure 110 serve as connecting wires for the thin film resistor 109. Moreover, the composition of the lead structure 110 can further fill the hole in the dielectric layer 105 to form the contact via 110V, thereby electrically connecting the lead structure 110 to the top metal layer 106. Details of other features of the semiconductor device 100D may be found in the related descriptions of FIG. 1 and FIG. 2, which will not be repeated here.

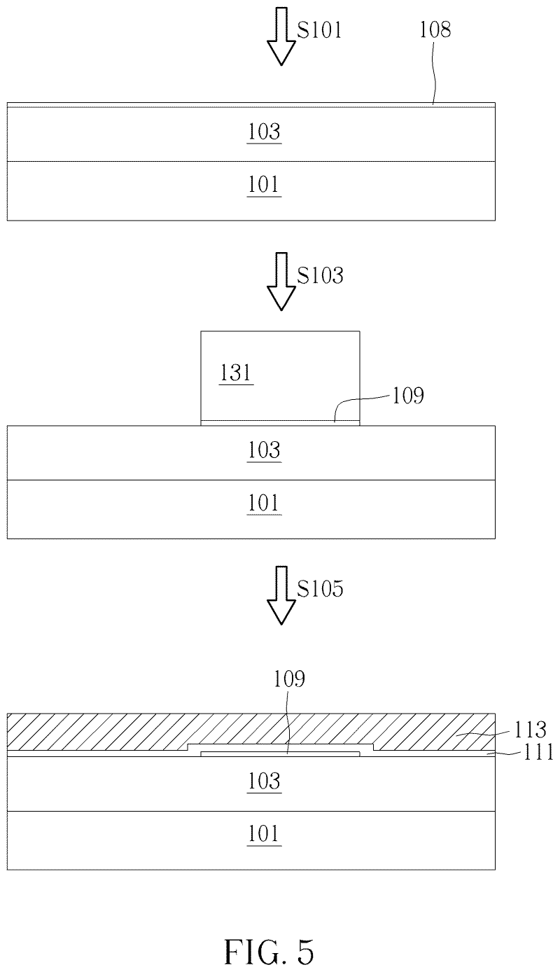

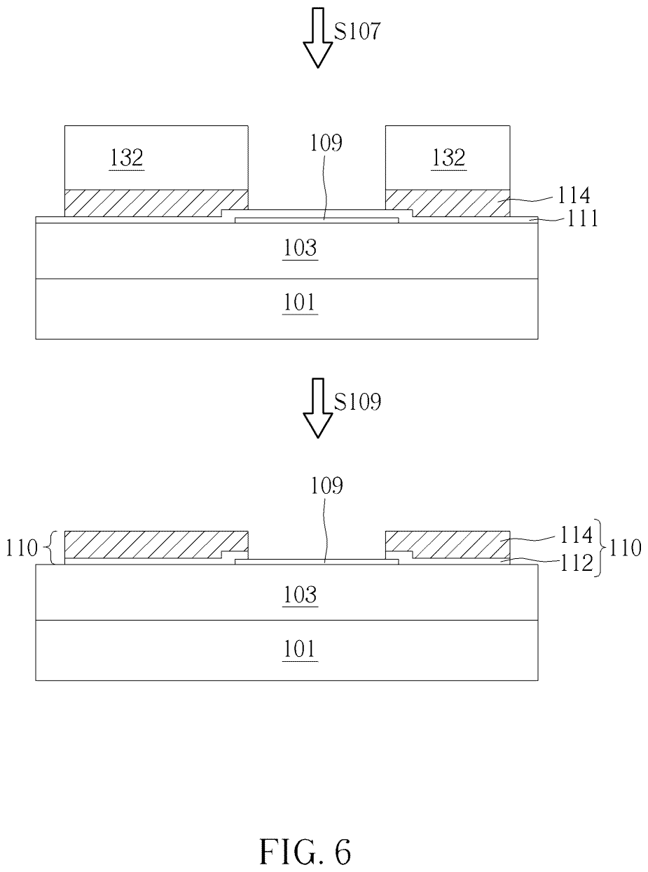

FIG. 5 and FIG. 6 are schematic cross-sectional views showing some stages in a method for fabricating the semiconductor device 100A according to an embodiment of the present disclosure. Referring to FIG. 5, in step S101, a substrate 101, such as a silicon substrate, is provided. A dielectric layer 103, such as a silicon oxide layer, is formed on the substrate 101. A thin film resistance material layer 108 is deposited on the dielectric layer 103 and then annealed to achieve a low temperature coefficient of resistance (TCR). In one embodiment, the thin film resistance material layer 108 is, for example, a silicon chromium (SiCr) layer with a thickness of 50 Å to 150 Å.

Still referring to FIG. 5, in step S103, a patterned photoresist 131 is formed on the thin film resistance material layer 108 by photoresist coating, exposure and development processes. The patterned photoresist 131 acts as a mask for dry etching or ion beam etching (IBE) of the thin film resistance material layer 108, thereby patterning the thin film resistance material layer 108 to form a thin film resistor 109. Still referring to FIG. 5, in step S105, a solvent such as N-methylpyrrolidone (NMP) is used to strip the patterned photoresist 131. Then, an etch stop material layer 111 and a conductive material layer 113 are deposited on the dielectric layer 103 in sequence to cover the thin film resistor 109. In one embodiment, the etch stop material layer 111 is, for example, a titanium tungsten (TiW) layer with a thickness of about 650 Å. The conductive material layer 113 includes a titanium nitride (TiN) layer with a thickness of about 550 Å stacked on an aluminum copper (AlCu) layer with a thickness of about 3000 Å.

Next, referring to FIG. 6, in step S107, another patterned photoresist 132 is formed on the conductive material layer 113. The patterned photoresist 132 acts as a mask for dry etching of the conductive material layer 113, and the conductive material layer 113 is patterned to form a conductive layer 114. Afterward, the etch stop material layer 111 is exposed and covers the thin film resistor 109. During the etching of the conductive material layer 113, because the etching selectivity of the conductive material layer 113 to the etch stop material layer 111 is greater than 7, for example, the etching selectivity of an aluminum copper (AlCu) layer to a titanium tungsten (TiW) layer is about 7 to 8, the etching of the conductive material layer 113 stops at the etch stop material layer 111. Therefore, the thin film resistor 109 is protected by the etch stop material layer 111 during the etching process that forms the conductive layer 114.

Still referring to FIG. 6, in step S109, the patterned photoresist 132 is removed. Then, the conductive layer 114 acts as a hard mask for wet etching of the etch stop material layer 111. For example, a hydrogen peroxide (H₂O₂) etching solution is used to pattern the etch stop material layer 111, thereby forming an etch stop layer 112 and exposing the thin film resistor 109. The etch stop layer 112 and the conductive layer 114 constitute a lead structure 110. Because the conductive layer 114 acts as a hard mask, the pattern of the etch stop layer 112 is self-aligned with the pattern of the conductive layer 114. Thus, the side surface of the conductive layer 114 is aligned with the side surface of the etch stop layer 112. In addition, the etching rate of a hydrogen peroxide (H₂O₂) etching solution on titanium tungsten (TiW) is more than ten times that on titanium nitride (TiN). Therefore, the titanium tungsten (TiW) layer is selected as the etch stop material layer 111. This ensures that the etch stop material layer 111 on the thin film resistor 109 is removed more effectively. Moreover, the hydrogen peroxide (H₂O₂) etching solution will not damage the thin film resistor 109. Thereafter, referring to FIG. 1, the passivation layer 120 is formed on the dielectric layer 103 to cover the thin film resistor 109 and the lead structure 110. Next, the opening 122 is formed in the dielectric layer 103 to expose the lead structure 110, thereby completing the semiconductor device 100A.

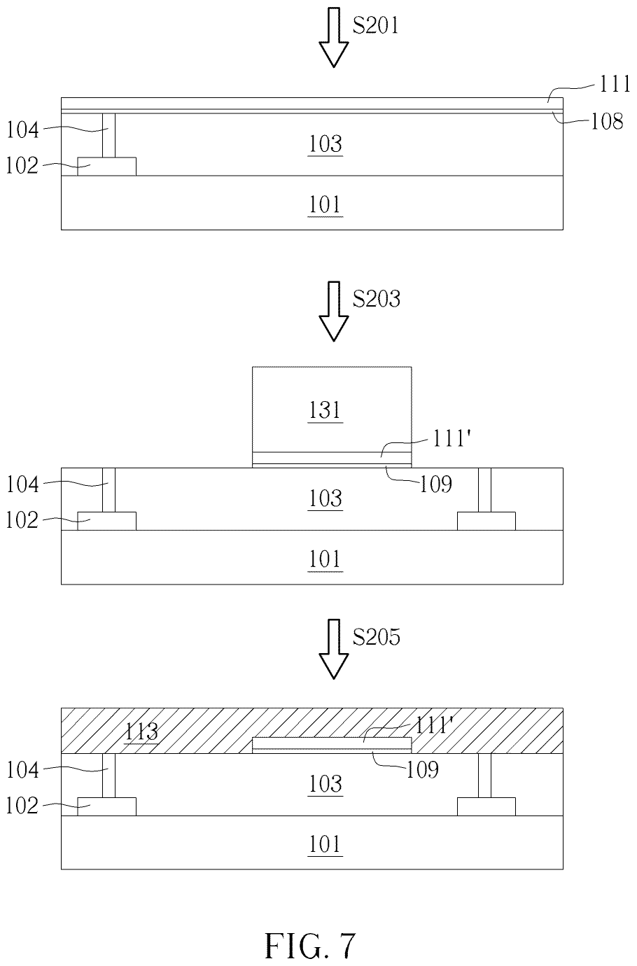

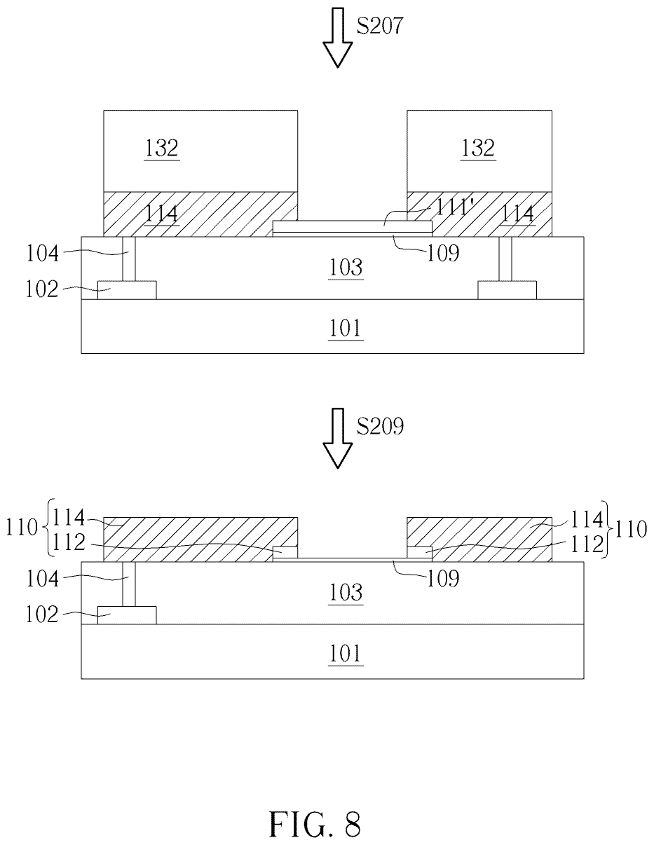

FIG. 7 and FIG. 8 are schematic cross-sectional views showing some stages in a method for fabricating the semiconductor device 100C according to another embodiment of the present disclosure. Referring to FIG. 7, in step S201, a substrate 101, such as a silicon substrate, is provided. A metal interconnection layer 102 is formed on the substrate 101 by deposition and patterning processes. A dielectric layer 103, such as a silicon oxide layer, is formed on the substrate 101 to cover the metal interconnection layer 102. A via 104 is formed in the dielectric layer 103 by etching, deposition and chemical mechanical planarization (CMP) processes. The via 104 is located on the metal interconnect layer 102, and is electrically connected to the metal interconnect layer 102. A thin film resistance material layer 108 is deposited on the dielectric layer 103 and then annealed. Afterward, an etch stop material layer 111 is deposited on the thin film resistance material layer 108. In one embodiment, the thin film resistance material layer 108 is, for example, a silicon chromium (SiCr) layer with a thickness of 50 Å to 150 Å. The etch stop material layer 111 is, for example, a titanium tungsten (TiW) layer with a thickness of about 650 Å.

Still referring to FIG. 7, in step S203, a patterned photoresist 131 is formed on the etch stop material layer 111. The patterned photoresist 131 acts as a mask for etching both the thin film resistance material layer 108 and the etch stop material layer 111 by dry etching or ion beam etching (IBE), thereby forming a thin film resistor 109. Furthermore, the pattern of a remaining etch stop material layer 111′ and the pattern of the thin film resistor 109 may be completely overlapped.

Still referring to FIG. 7, in step S205, a solvent such as N-methylpyrrolidone (NMP) is used to strip the patterned photoresist 131. Then, a conductive material layer 113 is deposited on the dielectric layer 103 and covers the side surfaces of both the remaining etch stop material layer 111′ and the thin film resistor 109. The conductive material layer 113 is in direct contact with and covers the dielectric layer 103. In some embodiments, the conductive material layer 113 includes a titanium nitride (TiN) layer with a thickness of about 550 Å, an aluminum copper (AlCu) layer with a thickness of about 3000 Å, and a titanium nitride (TiN) layer with a thickness of about 550 Å stacked from bottom to top. The bottommost TiN layer is in direct contact with and covers the dielectric layer 103 and the via 104. The middle AlCu layer is in direct contact with and covers the remaining etch stop material layer 111′.

Next, referring to FIG. 8, in step S207, another patterned photoresist 132 is formed on the conductive material layer 113. The patterned photoresist 132 acts as a mask for dry etching of the conductive material layer 113, thereby forming a conductive layer 114 and exposing the remaining etch stop material layer 111′. The remaining etch stop material layer 111′ completely covers the thin film resistor 109. Because the etching selectivity of the conductive material layer 113 to the etch stop material layer 111 is greater than 7, for example, the etching selectivity of the aluminum copper (AlCu) layer to the titanium tungsten (TiW) layer is about 7 to 8, the etching of the conductive material layer 113 stops at the remaining etch stop material layer 111′. Therefore, the thin film resistor 109 is protected by the remaining etch stop material layer 111′ during the etching process for forming the conductive layer 114.

Still referring to FIG. 8, in step S209, the patterned photoresist 132 is removed. The conductive layer 114 acts as a hard mask for wet etching of the remaining etch stop material layer 111′. For example, a hydrogen peroxide (H₂O₂) etching solution is used to form an etch stop layer 112 and expose the thin film resistor 109. The etch stop layer 112 and the conductive layer 114 constitute a lead structure 110. In the vertical projection direction, the pattern of the etch stop layer 112 is self-aligned with the pattern of the thin film resistor 109. Thereafter, referring to FIG. 3, the passivation layer 120 is formed on the dielectric layer 103 to cover the thin film resistor 109 and the lead structure 110. Next, the opening 122 is formed in the dielectric layer 103 to expose the lead structure 110, thereby completing the semiconductor device 100C.

In addition, a method for fabricating the semiconductor device 100B may refer to step S201 in FIG. 7. A substrate 101 is provided, and a metal interconnection layer 102 is formed on the substrate 101. A dielectric layer 103 is formed on the substrate 101 to cover the metal interconnection layer 102. A via 104 is formed in the dielectric layer 103 and located on the metal interconnect layer 102. The via 104 is electrically connected to the metal interconnect layer 102. Next, referring to steps S101, S103 and S105 of FIG. 5, and steps S107 and S109 of FIG. 6, a thin film resistor 109 and a lead structure 110 are formed on the dielectric layer 103 in sequence. The via 104 electrically connects the metal interconnect layer 102 to the lead structure 110. Thereafter, referring to FIG. 2, the passivation layer 120 is formed on the dielectric layer 103 to cover the thin film resistor 109 and the lead structure 110. Next, the opening 122 is formed in the dielectric layer 103 to expose the lead structure 110, thereby completing the semiconductor device 100B.

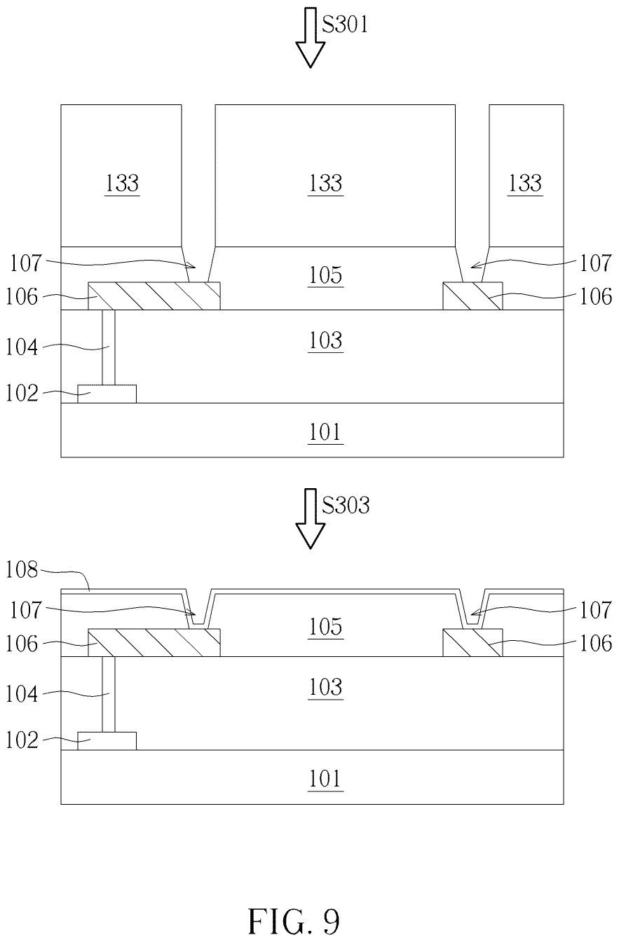

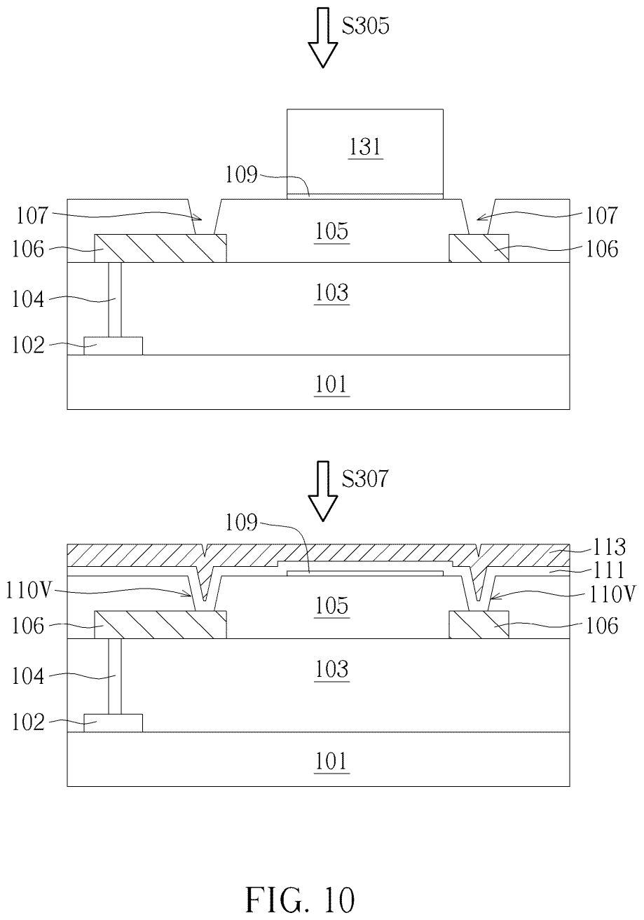

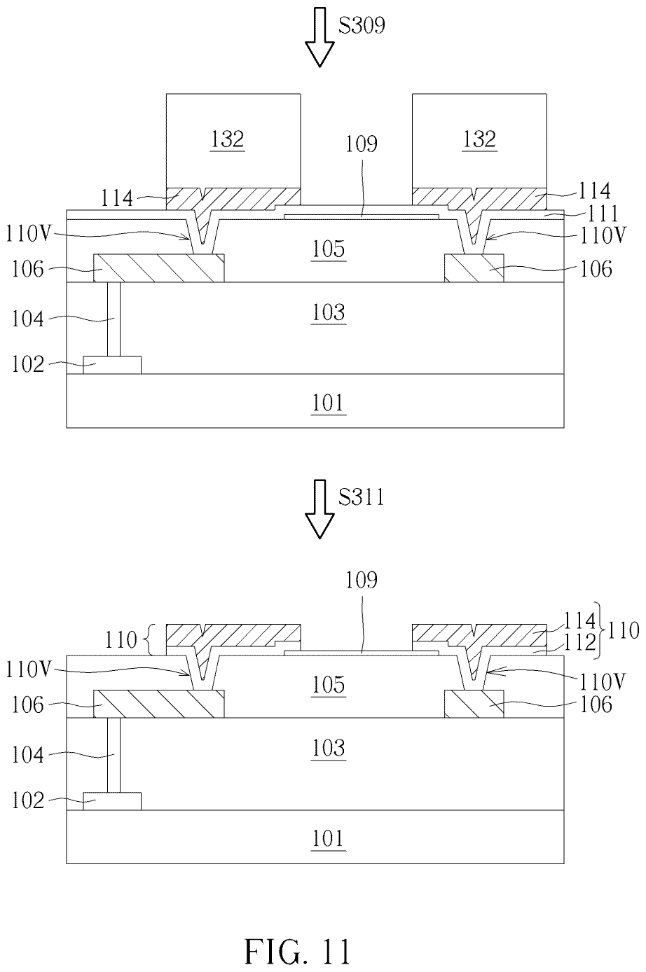

FIG. 9, FIG. 10 and FIG. 11 are schematic cross-sectional views showing some stages of a method for fabricating the semiconductor device 100D according to further another embodiment of the present disclosure. Referring to FIG. 9, in step S301, a substrate 101 is provided, and a metal interconnection layer 102 is formed on the substrate 101. A dielectric layer 103 is formed on the substrate 101 to cover the metal interconnection layer 102. A via 104 is formed in the dielectric layer 103 and located on the metal interconnection layer 102. The via 104 is electrically connected to the metal interconnection layer 102. A top metal layer 106 is formed on the dielectric layer 103 by deposition and patterning processes. Another dielectric layer 105 is deposited on the dielectric layer 103 to cover the top metal layer 106. A patterned photoresist 133 is formed on the dielectric layer 105. The patterned photoresist 133 acts as a mask for dry etching the dielectric layer 105 to form a hole 107, thereby exposing the top metal layer 106.

Still referring to FIG. 9, in step S303, the patterned photoresist 133 is removed. A thin film resistance material layer 108, such as a silicon chromium (SiCr) layer with a thickness of 50 Å to 150 Å, is conformally deposited on the dielectric layer 105 and in the hole 107. Then, the thin film resistance material layer 108 is annealed.

Next, referring to FIG. 10, in step S305, another patterned photoresist 131 is formed on the thin film resistance material layer 108. The patterned photoresist 131 acts as a mask for etching the thin film resistance material layer 108 by dry etching or ion beam etching (IBE) to form a thin film resistor 109. Meanwhile, the thin film resistance material layer 108 in the hole 107 is removed by the etching to expose the top metal layer 106. Still referring to FIG. 10, in step S307, a solvent such as N-methylpyrrolidone (NMP) is used to strip the patterned photoresist 131. An etch stop material layer 111 and a conductive material layer 113 are conformally deposited on the dielectric layer 105 and in the hole 107 in sequence to cover the thin film resistor 109. The etch stop material layer 111 and the conductive material layer 113 fill the hole 107 to form a contact via 110V. The contact via 110V is electrically connected to the top metal layer 106. In one embodiment, the etch stop material layer 111 may be a titanium tungsten (TiW) layer with a thickness of about 650 Å. The conductive material layer 113 may include a titanium nitride (TiN) layer with a thickness of about 550 Å stacked on an aluminum copper (AlCu) layer with a thickness of about 3000 Å.

Then, referring to FIG. 11, in step S309, another patterned photoresist 132 is formed on the conductive material layer 113. The patterned photoresist 132 acts as a mask for dry etching the conductive material layer 113 to form a conductive layer 114. Afterward, the etch stop material layer 111 is exposed and covers the thin film resistor 109.

Still referring to FIG. 11, in step S311, the patterned photoresist 132 is removed. The conductive layer 114 acts as a hard mask for wet etching of the etch stop material layer 111. For example, a hydrogen peroxide (H₂O₂) etching solution is used to form an etch stop layer 112 and expose the thin film resistor 109. The etch stop layer 112 and the conductive layer 114 constitute a lead structure 110. The contact via 110V electrically connects the top metal layer 106 to the lead structure 110. Thereafter, referring to FIG. 4, the passivation layer 120 is formed on the dielectric layer 105 to cover the thin film resistor 109 and the lead structure 110. Next, the common opening 123 is formed in the passivation layer 120 and the dielectric layer 105 to expose the top metal layer 106, thereby completing the semiconductor device 100D.

According to some embodiments of the present disclosure, the semiconductor devices include thin film resistors located between the passivation layer and the uppermost dielectric layer of the interconnect structure. The thin film resistor is fabricated independently and is separated from the interconnect structure. This reduces stress on the thin film resistor, thereby improving the electrical performance of the thin film resistor. In addition, a lead structure is in direct contact with and overlaps the end of the thin film resistor to create an electrical connection. The lead structure functions as both a connecting wire and a contact electrode. Therefore, there is no need to form an electrode and a contact via above the thin film resistor. The lead structure further serves as a top metal layer in the interconnect structure, thereby reducing the number of photomasks and process steps.

Moreover, in the semiconductor devices of the present disclosure, the lead structure is constituted by an etch stop layer and a conductive layer. The materials of the conductive layer and the etch stop layer exhibit a high etching selectivity greater than 7. During the dry etching process of forming the conductive layer, etching stops at the etch stop material layer, thereby protecting the thin film resistor. Furthermore, during the subsequent wet etching process of forming the etch stop layer, the conductive layer of the lead structure serves as a hard mask. The etching solution has a high etching rate for the etch stop layer, thus greatly reducing wet etching time and improving fabrication efficiency. Moreover, the etching solution does not damage the thin film resistor. Therefore, the embodiments of the present disclosure can improve the quality of the semiconductor devices including the thin film resistors, and save manufacturing costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a thin film resistor, disposed above the substrate, and having a first end and a second end;
a lead structure, disposed above the substrate, and comprising an etch stop layer and a conductive layer stacked on the etch stop layer, wherein the etch stop layer is in direct contact with and covers the first end and the second end of the thin film resistor; and
a passivation layer, covering the thin film resistor and the lead structure.

2. The semiconductor device of claim 1, wherein a composition of the etch stop layer comprises titanium tungsten (TiW) or titanium nitride (TiN), the conductive layer comprises a titanium nitride (TiN) layer stacked on an aluminum copper (AlCu) layer, the AlCu layer is in direct contact with the etch stop layer, and an etching selectivity of the conductive layer to the etch stop layer is greater than 7.

3. The semiconductor device of claim 1, further comprising:
a dielectric layer, disposed on the substrate, wherein the thin film resistor and the lead structure are disposed on the dielectric layer, and a bottom surface of the thin film resistor, a bottom surface of the lead structure, and a top surface of the dielectric layer are coplanar; and
an opening, disposed in the passivation layer to expose the lead structure.

4. The semiconductor device of claim 3, further comprising:
a metal interconnect layer, disposed in the dielectric layer; and
a via, disposed in the dielectric layer and located on the metal interconnection layer, wherein the lead structure comprises a top metal layer, and the via electrically connects the metal interconnection layer to the lead structure.

5. The semiconductor device of claim 1, wherein in a vertical projection direction, a side surface of the conductive layer is aligned with a side surface of the etch stop layer.

6. The semiconductor device of claim 1, wherein in a vertical projection direction, a side surface of the etch stop layer is aligned with a side surface of the thin film resistor, and the conductive layer covers both the side surface of the etch stop layer and the side surface of the thin film resistor.

7. The semiconductor device of claim 6, further comprising:
a dielectric layer, disposed on the substrate, wherein a bottom surface of the thin film resistor, a bottom surface of the conductive layer, and a top surface of the dielectric layer are coplanar;
a metal interconnect layer, disposed in the dielectric layer; and
a via, disposed in the dielectric layer and located on the metal interconnection layer, wherein the conductive layer comprises a top metal layer, and the via electrically connects the metal interconnection layer to the conductive layer.

8. The semiconductor device of claim 1, further comprising:
a dielectric layer, disposed above the substrate;
a top metal layer, disposed in the dielectric layer; and
a contact via, disposed in the dielectric layer, and comprising a hole filled with the etch stop layer and the conductive layer, wherein the contact via electrically connects the top metal layer to the lead structure.

9. The semiconductor device of claim 8, further comprising a common opening disposed in both the passivation layer and the dielectric layer to expose the top metal layer.

10. A method of fabricating a semiconductor device, comprising:
depositing a thin film resistance material layer above a substrate;
patterning the thin film resistance material layer to form a thin film resistor having a first end and a second end;
depositing an etch stop material layer and a conductive material layer above the substrate in sequence to cover the thin film resistor;
patterning the conductive material layer to form a conductive layer;
patterning the etch stop material layer to form an etch stop layer, wherein the etch stop layer and the conductive layer constitute a lead structure, and the etch stop layer is in direct contact with and covers the first end and the second end of the thin film resistor; and
forming a passivation layer to cover the thin film resistor and the lead structure.

11. The method of claim 10, wherein forming the conductive layer comprises:
forming a patterned photoresist on the conductive material layer; and
etching the conductive material layer by using the patterned photoresist as a mask to form the conductive layer, wherein the etch stop material layer is exposed and covers the thin film resistor.

12. The method of claim 10, wherein forming the etch stop layer comprises:
etching the etch stop material layer by using the conductive layer as a hard mask to form the etch stop layer, wherein the thin film resistor is exposed, and a side surface of the conductive layer is aligned with a side surface of the etch stop layer.

13. The method of claim 10, further comprising:
forming a dielectric layer on the substrate, wherein the thin film resistance material layer is deposited on the dielectric layer;
depositing the etch stop material layer and the conductive material layer on the dielectric layer in sequence after the thin film resistor is formed; and
forming an opening in the passivation layer to expose the lead structure.

14. The method of claim 10, further comprising:
forming a dielectric layer on the substrate, wherein the thin film resistance material layer and the etch stop material layer are deposited on the dielectric layer in sequence;
forming a metal interconnect layer in the dielectric layer;
forming a via in the dielectric layer and located on the metal interconnect layer, wherein the via electrically connects the metal interconnect layer to the lead structure; and
forming an opening in the passivation layer to expose the lead structure.

15. The method of claim 14, wherein forming the thin film resistor and the etch stop layer comprises:
forming a patterned photoresist on the etch stop material layer;
etching both the thin film resistance material layer and the etch stop material layer by using the patterned photoresist as a mask to form the thin film resistor, wherein a remaining etch stop material layer covers the thin film resistor; and
etching the remaining etch stop material layer by using The conductive layer as a hard mask to form the etch stop layer, wherein the thin film resistor is exposed, and a side surface of the etch stop layer is aligned with a side surface of the thin film resistor.

16. The method of claim 15, wherein after etching both the thin film resistance material layer and the etch stop material layer, the conductive material layer covers the etch stop material layer, the side surface of the thin film resistor and the dielectric layer.

17. The method of claim 10, further comprising:
forming a dielectric layer above the substrate;
forming a top metal layer in the dielectric layer; and
forming a hole in the dielectric layer to expose the top metal layer, wherein the thin film resistance material layer is conformally deposited on the dielectric layer and in the hole.

18. The method of claim 17, wherein forming the thin film resistor comprises:
forming a patterned photoresist on the thin film resistance material layer; and
etching the thin film resistance material layer by using the patterned photoresist as a mask to form the thin film resistor, wherein the thin film resistance material layer in the hole is removed to expose the top metal layer.

19. The method of claim 18, wherein the etch stop material layer and the conductive material layer are deposited on the dielectric layer and are conformally deposited in the hole to form a contact via, and the contact via electrically connects the top metal layer to the lead structure.

20. The method of claim 17, further comprising forming a common opening in the passivation layer and the dielectric layer to expose the top metal layer.
